(19) United States
(12) Patent Application Publication
(10) Pub. No.: US 2026/0310719 A1
(43) Pub. Date: Oct. 8, 2026

(54) METHOD AND SYSTEM FOR SEARCH OF RESIDENTIAL HOUSE PLANS

(71) Applicants: Alireza SEPEHRIFAR, Tabriz (IR); Habib SHAHHOSEINI, Tabriz (IR); Morteza KHALILZADEH BAVIL, Tabriz (IR); Mohammadreza HATAMI MATANAGH, Tabriz (IR)

(72) Inventors: Alireza SEPEHRIFAR, Tabriz (IR); Habib SHAHHOSEINI, Tabriz (IR); Morteza KHALILZADEH BAVIL, Tabriz (IR); Mohammadreza HATAMI MATANAGH, Tabriz (IR)

(21) Appl. No.: 19/589,289

(22) PCT Filed: Sep. 23, 2022
(86) PCT No.: PCT/IB2022/059007

§ 371 Date: May 21, 2026

Related U.S. Application Data
(60) Provisional application No. 63/254,544, filed on Oct. 12, 2021.

(51) Int. Cl. G06F 16/538; G06F 30/13

(52) U.S. Cl. CPC G06F 16/538; G06F 30/13

(57) ABSTRACT

A method for search of residential house plans. The method includes receiving one or more house features from a first user, mapping the one or more house features to one or more predefined numbers of a plurality of predefined numbers stored in a database by mapping each of the one or more house features to a respective predefined number of the one or more predefined numbers, and finding a set of residential house plans stored in the database by mapping the one or more predefined numbers to each residential house plan in the set.

### TECHNICAL FIELD

The present disclosure generally relates to architecture, and particularly, to residential house plans.

### BACKGROUND ART

Multiplicity of architecture plans and increasing changes in interests of residential houses' residents and the necessity of utilizing plans of previous architectures in current plans have increased a need for searching and analyzing high volume of extant information by considering users' demands. Currently, there are several computer programs that provide layouts for designing and processing residential house plans [U.S. Pat. Nos. 6,836,752 B2, 11,403,435 B2, and 11,442,982 B2]. However, current approaches mostly utilize image processing techniques to extract information from visual representations of residential house plans which may need high computational cost. As a result, current approaches may have limited usage in searching residential house plans due to a large amount of time that may be required for processing a large number of images. There is, therefore, a need for a cost-efficient method that may facilitate searching in architectural designs.

### SUMMARY OF THE DISCLOSURE

This summary is intended to provide an overview of the subject matter of the present disclosure, and is not intended to identify essential elements or key elements of the subject matter, nor is it intended to be used to determine the scope of the claimed implementations. The proper scope of the present disclosure may be ascertained from the claims set forth below in view of the detailed description below and the drawings.

In one general aspect, the present disclosure describes an exemplary method for search of residential house plans. An exemplary method may include receiving one or more house features from a first user, mapping the one or more house features to one or more predefined numbers of a first plurality of predefined numbers stored in a database by mapping each of the one or more house features to a respective predefined number of the one or more predefined numbers, and finding a set of residential house plans stored in the database by mapping the one or more predefined numbers to each residential house plan in the set. An exemplary method may further include outputting one or more residential house plans in the set responsive to finding the set.

An exemplary method may further include adding a given residential house plan to the database. In an exemplary embodiment, adding the given residential house plan to the database may include dividing the given residential house plan to a plurality of spaces, dividing each of the plurality of spaces to a respective plurality of subspaces, receiving characteristics of the given residential house plan by receiving a plurality of subspace features for each respective subspace of each respective plurality of subspaces from a second user, mapping the characteristics to a second plurality of predefined numbers by mapping the plurality of subspace features to a respective predefined number of the second plurality of predefined numbers, and storing the second plurality of predefined numbers and an image of the given residential house plan in the database.

In an exemplary embodiment, each of receiving the plurality of house features and receiving the plurality of subspace features may include at least one of receiving a type of one or more residential units, receiving a geographical situation of each of the one or more residential units, receiving a score of each of the one or more residential units, receiving building dimensions, receiving a location of one or more land passages, receiving a number of bedrooms, and receiving a plan code. In an exemplary embodiment, receiving the type of the one or more residential units may include receiving one of pillar, wall, window, door, lift, staircase, entrance, corridor, balcony, terrace, console, duct, storage room, filter, lobby, patio, void, pool, flower bed, kitchen, bathroom, toilet, laundry room, scullery, sewing room, dressing room, dining room, living room, TV room, study room, music room, billiard room, game room, recreation room, library, home cinema, master bedroom, kids room, guest room, closet, sick room, and worker room. In an exemplary embodiment, receiving the geographical situation may include receiving one of north west, north, north east, west northwest, near to north, east northeast, west, center, east, west southwest, near to south, east southeast, south west, south, and south east.

In an exemplary embodiment, receiving the building dimensions may include receiving a building width and a building length. In an exemplary embodiment, receiving the location of the one or more land passages may include receiving at least one of north, east, south, and west. In an exemplary embodiment, receiving the plan code may include receiving a four-digit number. In an exemplary embodiment, each of mapping each of the one or more house features to a respective predefined number of the one or more predefined numbers and mapping each of the plurality of subspace features to a respective predefined number of the second plurality of predefined numbers may include mapping the geographical situation to first three digits of a six-digit number, mapping the type of the one or more residential units to last two digits of the six-digit number, and mapping the score to a fourth digit of the six-digit number.

In an exemplary embodiment, each of mapping each of the one or more house features to a respective predefined number of the one or more predefined numbers and mapping each of the plurality of subspace features to a respective predefined number of the second plurality of predefined numbers may further include mapping each of the north, the east, the south, and the west to a respective digit of first four digits of a sixteen-digit number, mapping the building width to second four digits of the sixteen-digit number, mapping the building length to third four digits of the sixteen-digit number, and mapping the four-digit number to last four digits of the sixteen-digit number. In an exemplary embodiment, mapping each of the north, the east, the south, and the west to a respective digit of the first four digits of the sixteen-digit number may include setting the respective digit to a first value responsive to the each of the north, the east, the south, and the west being received and setting the respective digit to a second value responsive to the each of the north, the east, the south, and the west not being received.

Other exemplary systems, methods, features and advantages of the implementations will be, or will become, apparent to one of ordinary skill in the art upon examination of the following figures and detailed description. It is intended that all such additional systems, methods, features and advantages be included within this description and this summary, be within the scope of the implementations, and be protected by the claims herein.

### BRIEF DESCRIPTION OF THE DRAWINGS

The drawing figures depict one or more implementations in accord with the present teachings, by way of example only, not by way of limitation. In the figures, like reference numerals refer to the same or similar elements.

FIG. 1A shows a flowchart of a method for search of residential house plans, consistent with one or more exemplary embodiments of the present disclosure.

FIG. 1B shows a flowchart for mapping house features to predefined numbers, consistent with one or more exemplary embodiments of the present disclosure.

FIG. 1C shows a flowchart for adding a given residential house plan to a database, consistent with one or more exemplary embodiments of the present disclosure.

FIG. 2A shows a window of a computer application for receiving one or more house features from a first user, consistent with one or more exemplary embodiments of the present disclosure.

FIG. 2B shows a window of a computer application for defining a user of the computer application, consistent with one or more exemplary embodiments of the present disclosure.

FIG. 3 shows geographical situations in a residential house plan, consistent with one or more exemplary embodiments of the present disclosure.

FIG. 4A shows an image of a given residential house plan, consistent with one or more exemplary embodiments of the present disclosure.

FIG. 4B shows a plan template divided into subspaces, consistent with one or more exemplary embodiments of the present disclosure.

FIG. 4C shows an image of a residential house plan divided into subspaces, consistent with one or more exemplary embodiments of the present disclosure.

FIG. 4D shows subspaces of residential units in a residential house plan mapped to predefined numbers, consistent with one or more exemplary embodiments of the present disclosure.

FIG. 5 shows a high-level functional block diagram of a computer system, consistent with one or more exemplary embodiments of the present disclosure.

### DESCRIPTION OF EMBODIMENTS

In the following detailed description, numerous specific details are set forth by way of examples in order to provide a thorough understanding of the relevant teachings. However, it should be apparent that the present teachings may be practiced without such details. In other instances, well known methods, procedures, components, and/or circuitry have been described at a relatively high-level, without detail, in order to avoid unnecessarily obscuring aspects of the present teachings.

The following detailed description is presented to enable a person skilled in the art to make and use the methods and devices disclosed in exemplary embodiments of the present disclosure. For purposes of explanation, specific nomenclature is set forth to provide a thorough understanding of the present disclosure. However, it will be apparent to one skilled in the art that these specific details are not required to practice the disclosed exemplary embodiments. Descriptions of specific exemplary embodiments are provided only as representative examples. Various modifications to the exemplary implementations will be readily apparent to one skilled in the art, and the general principles defined herein may be applied to other implementations and applications without departing from the scope of the present disclosure. The present disclosure is not intended to be limited to the implementations shown, but is to be accorded the widest possible scope consistent with the principles and features disclosed herein.

Herein is disclosed an exemplary method and system for search of residential house plans. An exemplary method may receive features of different residential units in a building (such as type and geographical situation) and map the received features to predefined numbers. In an exemplary embodiment, each “predefined number” may correspond to a different feature of a residential unit and may have been stored in a database prior to starting the method. An exemplary database may include several residential house plans with characteristics that have been mapped to corresponding predefined numbers. An exemplary method may then search in the database to find residential house plans that match the mapped predefined numbers.

An exemplary method may also include creating and expanding the database by adding information of new residential house plans to the database. To do so, characteristics of a new exemplary residential house plan may be extracted by obtaining features of each residential unit in the plan. Exemplary obtained features may then be mapped to corresponding predefined numbers which may be added to the database. As a result, useful data of a large number of residential house plans may be stored in an exemplary database in a number format with a much smaller size. Therefore, different characteristics of house plans may be searched and analyzed within a rich database in a considerably shorter amount of time compared to conventional methods.

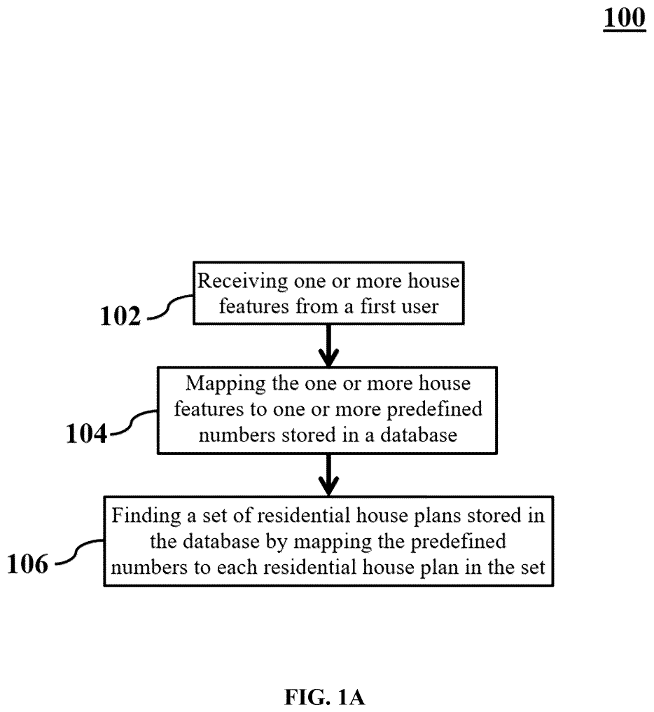

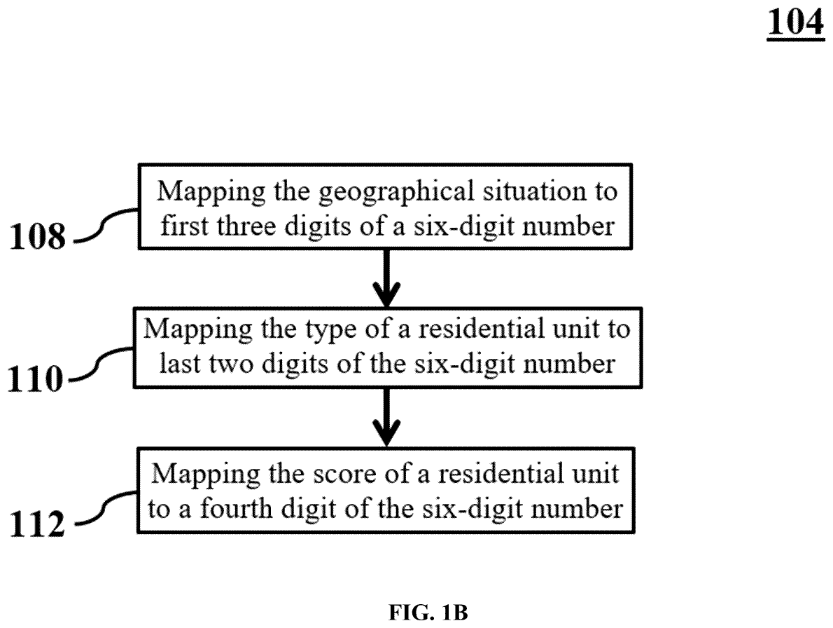

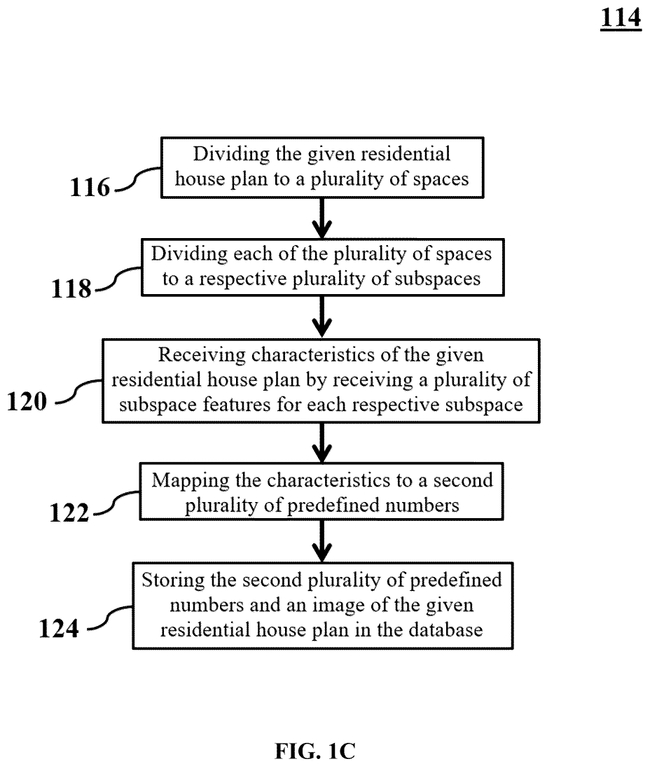

FIG. 1A shows a flowchart of a method for search of residential house plans, consistent with one or more exemplary embodiments of the present disclosure. An exemplary method 100 may include receiving one or more house features from a first user (step 102), mapping the one or more house features to one or more predefined numbers of a first plurality of predefined numbers stored in a database (step 104), and finding a set of residential house plans stored in the database by mapping the predefined numbers to each residential house plan in the set. (step 106).

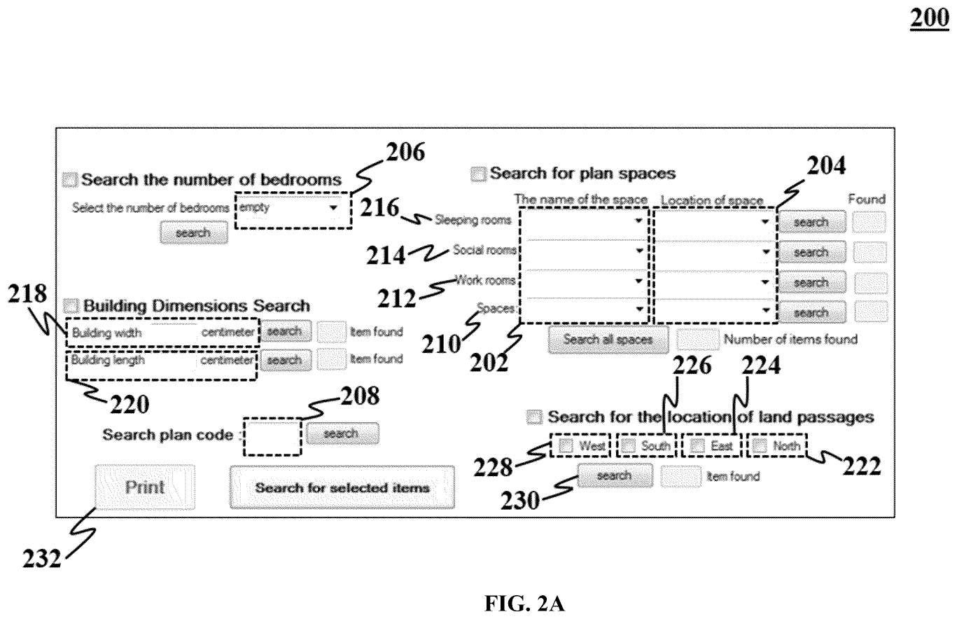

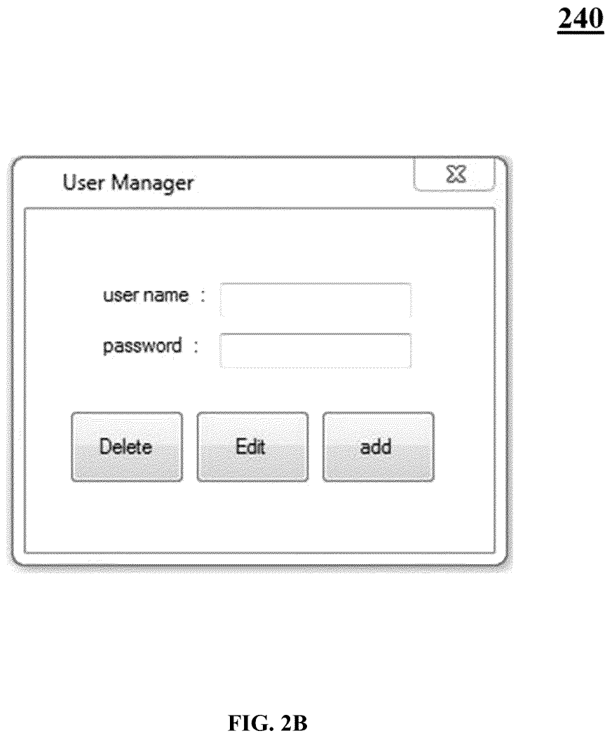

In further detail regarding step 102, FIG. 2A shows a window of a computer application for receiving one or more house features from a first user, consistent with one or more exemplary embodiments of the present disclosure. In an exemplary embodiment, a “first user” may refer to a user that inputs data of exemplary house features to a computer application through a window 200. Exemplary house features may include a type of one or more residential units (which may be entered or selected at fields 202 by the first user), geographical situations of residential units (which may be entered at fields 204 by the first user), a score of a residential unit, building dimensions, a location of one or more land passages, a number of bedrooms (which may be entered at a field 206 by the first user), and a plan code 208.

An exemplary type of a residential unit may include spaces 210 (such as pillar, wall, window, door, lift, staircase, entrance, corridor, balcony, terrace, console, duct, storage room, filter, lobby, patio, void, pool, and flower bed), work rooms 212 (such as kitchen, bathroom, toilet, laundry room, scullery, sewing room, and dressing room), social rooms 214 (such as dining room, living room, TV room, study room, music room, billiard room, game room, recreation room, library, and home cinema), and sleeping rooms 216 (such as master bedroom, kids room, guest room, closet, sick room, and worker room).

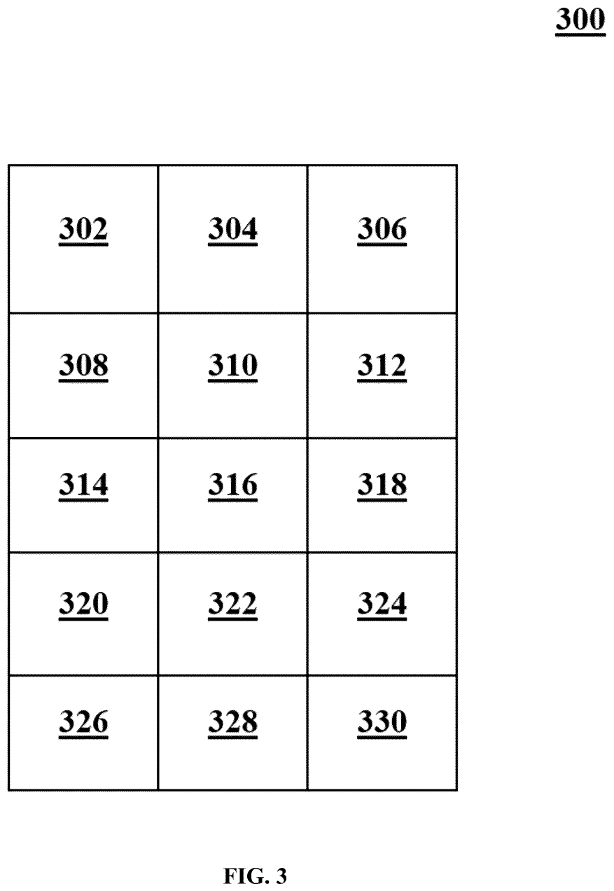

FIG. 3 shows geographical situations in a residential house plan, consistent with one or more exemplary embodiments of the present disclosure. An exemplary residential house plan 300 may be divided into fifteen blocks in five rows and three columns. Each exemplary block of residential house plan 300 may be located in a different geographical situation. Exemplary geographical situations may include north west 302, north 304, north east 306, west northwest 308, near to north 310, east northeast 312, west 314, center 316, east 318, west southwest 320, near to south 322, east southeast 324, south west 326, south 328, and south east 330.

Referring again to FIG. 2A, an exemplary building dimensions may include a building width 218 and a building length 220. In an exemplary embodiment, building width 218 and building length 220 may be entered in centimeters (cm). Exemplary locations of land passages may include north 222, east 224, south 226, and west 228. In an exemplary embodiment, a four-digit number may be entered in field 208 as the plan code.

Referring again to FIG. 1A, step 104 may include mapping one or more house features to one or more predefined numbers by mapping each house feature to a respective predefined number. FIG. 1B shows a flowchart for mapping house features to predefined numbers, consistent with one or more exemplary embodiments of the present disclosure. In an exemplary embodiment, mapping each house feature to a respective predefined number in step 104 may include mapping the geographical situation to first three digits of a six-digit number (step 108), mapping the type of a residential unit to last two digits of the six-digit number (step 110), and mapping the score of the residential unit to a fourth digit of the six-digit number (step 112).

In an exemplary embodiment, step 108 may include mapping the geographical situation to a three-digit number that may form the first three digits of the six-digit number. Table 1 shows exemplary three-digit numbers corresponding to each geographical situation of residential house plan 300 in FIG. 3.

TABLE 1
Three-digit numbers corresponding to each geographical
situation of a residential house plan.

| Geographical Situation | Number |
|---|---|
| North west 302 | 111 |
| North 304 | 112 |
| North east 306 | 113 |
| West northwest 308 | 114 |
| Near to north 310 | 115 |
| East northeast 312 | 116 |
| West 314 | 117 |
| Center 316 | 118 |
| East 318 | 119 |
| West southwest 320 | 120 |
| Near to south 322 | 121 |
| East southeast 324 | 122 |
| South west 326 | 123 |
| South 328 | 124 |
| South east 330 | 125 |

In an exemplary embodiment, step 110 may include mapping the type of a residential unit to a two-digit number. An exemplary two-digit number may form the last two digits of the six-digit number of the six-digit number. Tables 2a, 2b, 2c, and 2d respectively show exemplary two-digit numbers corresponding to each type of spaces 210, work rooms 212, social rooms 214, and sleeping rooms 216 described above.

TABLE 2a
Two-digit numbers corresponding to different
types of spaces in a residential house plan.

| Type | Number |
|---|---|
| Pillar | 11 |
| Wall | 12 |
| Window | 13 |
| Door | 14 |
| Lift | 15 |
| Staircase | 16 |
| Entrance | 17 |
| Corridor | 18 |
| Balcony | 19 |
| Terrace | 20 |
| Consul | 21 |
| Duct | 22 |
| Closet | 23 |
| Filter | 24 |
| Lobby | 25 |
| Patio | 26 |
| Void | 27 |
| Pool | 28 |
| Flower bed | 29 |

TABLE 2b
Two-digit numbers corresponding to different types
of social rooms in a residential house plan.

| Type | Number |
|---|---|
| Kitchen | 31 |
| Bathroom | 32 |
| Toilet | 33 |
| Laundry room | 34 |
| Scullery | 35 |
| Sewing room | 36 |
| Dressing room | 37 |

TABLE 2c
Two-digit numbers corresponding to different
types of spaces in a residential house plan.

| Type | Number |
|---|---|
| Dining room | 51 |
| Living room | 52 |
| TV room | 53 |
| Study room | 54 |
| Music room | 55 |
| Billiard room | 56 |
| Game room | 57 |
| Recreation room | 58 |
| Library | 59 |
| Home cinema | 60 |

TABLE 2d
Two-digit numbers corresponding to different types
of sleeping rooms in a residential house plan.

| Type | Number |
|---|---|
| Master bedroom | 71 |
| Kids room | 72 |
| Guest room | 73 |
| Closet | 74 |
| Sick room | 75 |
| Worker room | 76 |

In an exemplary embodiment, step 112 may include mapping the score of the residential unit to the fourth digit of the six-digit number. Based on different aspects of the residential unit (for example, type and geographical situation of the residential unit in the residential house plan), an exemplary score between 1 and 9 may be assigned to the residential unit by an exemplary first user. An exemplary score may then be placed in step 112 in the fourth digit's position of the six-digit number.

Referring to FIGS. 1A and 2A, in an exemplary embodiment, mapping one or more house features to one or more predefined numbers in step 104 may further include mapping locations of land passages, building dimensions, and plan code 208 to a sixteen-digit number. In an exemplary embodiment, each of north 222, east 224, south 226, and west 228 may be mapped to a respective digit of first four digits of a sixteen-digit number. An exemplary respective digit of the first four digits may be set to a first value responsive to the each of north 222, east 224, south 226, and west 228 being received. In an exemplary embodiment, the first value may be set to one. For example, a first digit of the first four digits may be set to 1 if north 222 is received by the first user. An exemplary respective digit of the first four digits may be set to a second value responsive to the each of north 222, east 224, south 226, and west 228 not being received. In an exemplary embodiment, the second value may be set to two. For example, a second digit of the first four digits may be set to 2 if east 224 is not received by the first user. Therefore, as an example, if residential house plan 300 in FIG. 3 includes one land passage at the east and another land passage at the west (i.e., east 224 and west 228 are received by the first user), the first four digits of the sixteen-digit number may be set to 2121.

In an exemplary embodiment, building width 218 may be mapped to second four digits of the sixteen-digit number. An exemplary four-digit number showing building width 218 in cm may be copied to the second four digits' position in the sixteen-digit number. Therefore, in an exemplary embodiment, the second four digits of the sixteen-digit number may represent building width 218 in cm. In an exemplary embodiment, building length 220 may be mapped to third four digits of the sixteen-digit number. An exemplary four-digit number showing building length 220 in cm may be copied to the third four digits' position in the sixteen-digit number. Therefore, in an exemplary embodiment, the third four digits of the sixteen-digit number may represent building length 220 in cm. In an exemplary embodiment, plan code 208 may be mapped to last four digits of the sixteen-digit number. An exemplary four-digit number representing plan code 208 may be copied to the last four digits' position in the sixteen-digit number.

In an exemplary embodiment, step 106 may include finding a set of residential house plans that are stored in the database. An exemplary search command 230 in window 200 of FIG. 2A may be selected for finding the set of residential house plans. For each exemplary residential house plan in the database, a plurality of six-digit numbers may have been stored in the database. Each exemplary six-digit number may represent a feature of a corresponding residential house plan in the database and may be interpreted similar to the six-digit number described above in steps 108-112 described above. In addition, an exemplary sixteen-digit number (analogous to the sixteen-digit number described above in step 104) may have also been stored in the database for a corresponding residential house plan. Therefore, in an exemplary embodiment, finding the set of residential house plans in step 106 may include mapping the predefined numbers to each residential house plan in the database that correspond to the predefined numbers. Exemplary predefined numbers may include six-digit or sixteen-digit numbers or portions of them that are formed according to step 104 described above. For example, if the first user selects a living room at a northwest situation of a residential house plan with a score of 1 in window 200 of FIG. 2A as a house feature in step 102, the selected house feature may be mapped to a six-digit number 111152 according to Tables 1 and 2a and steps 108-112 described above. However, in an exemplary embodiment, the first user may enter fewer aspects of a residential unit as a house feature. For example, if the first user only enters a type of a residential unit as a living room in field 202, the entered house feature may be mapped to a six-digit number xxxx52, in which “x” shows an undefined digit in the six-digit number.

In an exemplary embodiment, if the received house features in step 102 are mapped to predefined six-digit or sixteen-digit numbers with no undefined digits in step 106, the database may be searched in step 106 to find the exact six-digit or sixteen-digit numbers. An exemplary set may then be obtained that includes all residential house plans in the database with one or more features that are mapped to the found numbers.

In an exemplary embodiment, if the received house features in step 102 are mapped to six-digit or sixteen-digit numbers with one or more undefined digits in step 106, the set database may be searched in step 106 to find all six-digit or sixteen-digit numbers that have same defined digits with the predefined numbers that are obtained in step 104. For example, if number xxxx52 is obtained in step 104, all six-digit numbers in the database with last two digits equal to “52” may be found. An exemplary set may then be obtained that includes all residential house plans in the database with one or more features that are mapped to the found numbers.

In an exemplary embodiment, method 100 may further include outputting the residential house plans in the set responsive to finding the set. After an exemplary set is found in step 106, an image each of the residential house plans in the set may be outputted in a format selected by the first user, such as portable document format (pdf), jpeg, etc. An exemplary print command 232 in window 200 of FIG. 2A may be selected for outputting one or more of the residential house plans in the set according to the first user's selection.

In an exemplary embodiment, method 100 may further include adding a given residential house plan to the database. FIG. 1C shows a flowchart for adding a given residential house plan to a database, consistent with one or more exemplary embodiments of the present disclosure. An exemplary flowchart 114 may include dividing the given residential house plan to a plurality of spaces (step 116), dividing each of the plurality of spaces to a respective plurality of subspaces (step 118), receiving characteristics of the given residential house plan by receiving a plurality of subspace features for each respective subspace (step 120), mapping the characteristics to a second plurality of predefined numbers (step 122), and storing the second plurality of predefined numbers and an image of the given residential house plan in the database (step 124).

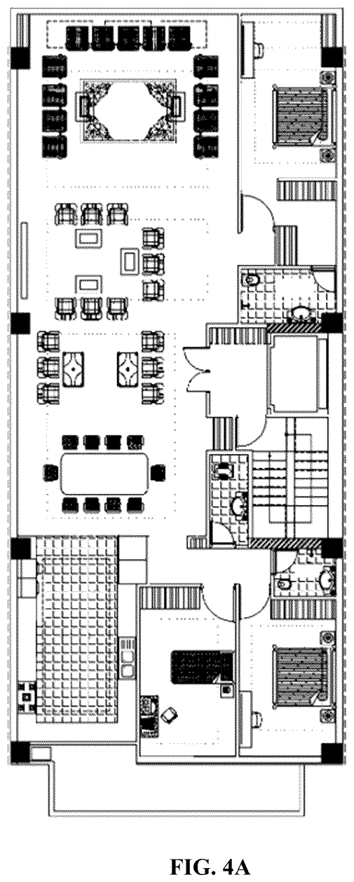

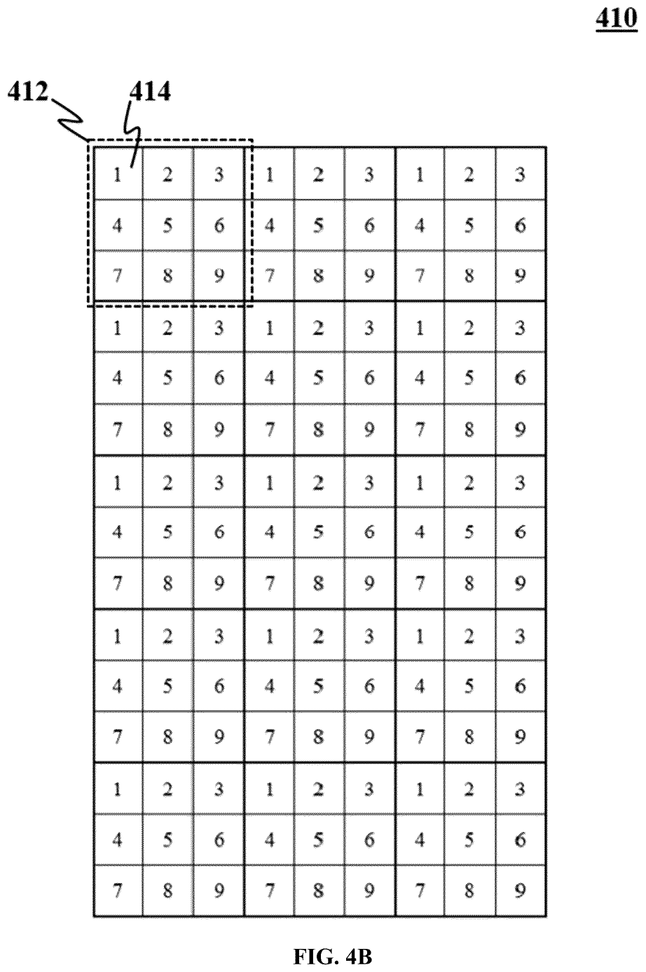

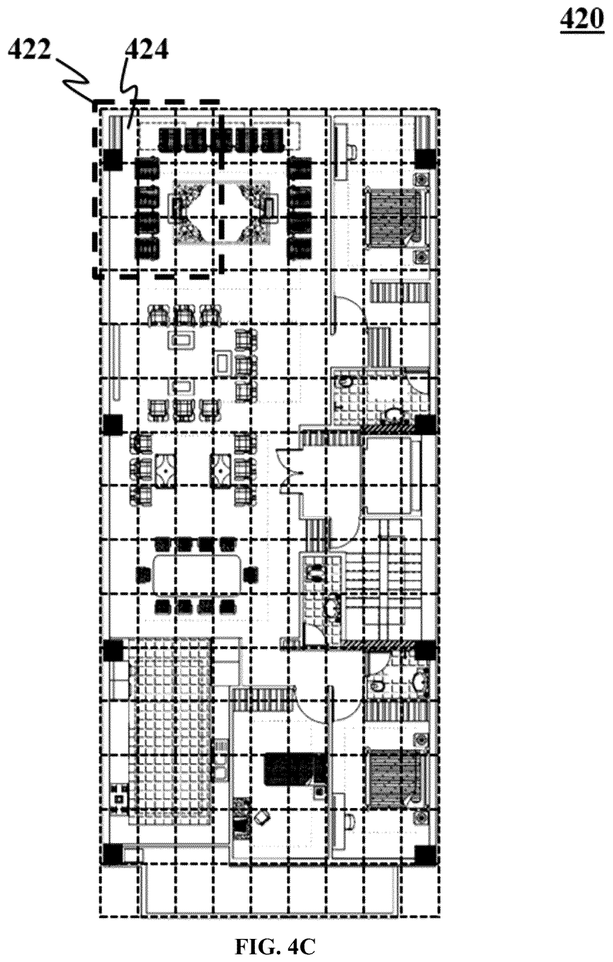

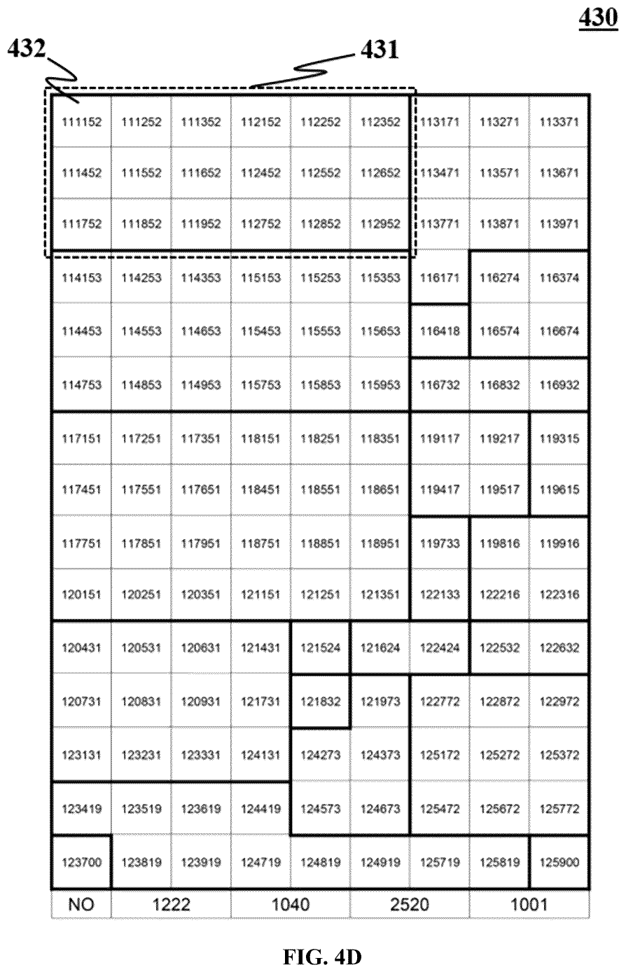

In further detail regarding step 116, FIG. 4A shows an image of a given residential house plan, consistent with one or more exemplary embodiments of the present disclosure. An exemplary given residential house plan 400 may be divided in step 116 to a plurality of spaces. An exemplary plurality of spaces may be positioned in fifteen blocks in five rows and three columns be similar to the blocks of residential house plan 300 in FIG. 3 and may be similarly located at geographical situations of FIG. 3.

For further detail with respect to step 118, FIG. 4B shows a plan template divided into subspaces, consistent with one or more exemplary embodiments of the present disclosure. An exemplary template 410 may be divided into fifteen blocks in five rows and three columns similar to residential house plan 300 in FIG. 3. Each exemplary block of template 410 may be located in a geographical situation similar to a corresponding block of residential house plan 300. For example, a block 412 may be located in north west 302. Each exemplary block of template 410 may be divided into a plurality of subspaces located in three rows and three columns. As a result, in an exemplary embodiment, there may be nine subspaces in each block of template 410. Therefore, there may be a total of fifteen rows and nine columns of subspaces in template 410. In an exemplary embodiment, all subspaces of a single block of template 410 may have a same geographical situation of that block. For example, all subspaces inside block 412 may be located in north west 302.

FIG. 4C shows an image of a residential house plan divided into subspaces, consistent with one or more exemplary embodiments of the present disclosure. An exemplary residential house plan 420 may be similar to given residential house plan 400 that is divided into subspaces according to template 410. In an exemplary embodiment, residential house plan 420 may be matched with template 410 so that each area in residential house plan 420 may be matched with a block in template 410 with a same geographical situation. For example, an area 422 in residential house plan 420 may be matched with block 412 and may be located in north west 302. Subsequently, in an exemplary embodiment, each area in residential house plan 420 may include a plurality of sub-areas that are matched with a corresponding plurality of subspaces. For example, area 422 may include nine sub-areas that are matched with subspaces inside block 412. As a result, each area (i.e., space) in residential house plan 420 may be divided into a plurality of subspaces that have a same geographical situation as of the divides area.

In further detail with regards to step 120, in an exemplary embodiment, receiving characteristics of given residential house plan 400 may include receiving a plurality of subspace features for each respective subspace of each respective plurality of subspaces. In an exemplary embodiment, a separate set of characteristics may be received for each space of given residential house plan 400. Each exemplary set of characteristics may include a number of features for subspaces inside the space. For example, for each of the nine subspaces inside block 412 a different feature may be received. To receive an exemplary feature for each subspace, the subspace may be matched with a corresponding sub-area in an exemplary image of given residential house plan 400. Each exemplary sub-area may determine a feature of a matching subspace of template 410. For example, a subspace 414 in FIG. 4B may be matched with a sub-area 424 in FIG. 4C, which is a part of a living room and is located in north west 302 and has a score of 1. Therefore, in an exemplary embodiment, features of sub-area 424 may be received as features of subspace 414. In an exemplary embodiment, similar features that are received in step 102 discussed above may also be received in step 120 for each subspace of given residential house plan 400. Exemplary subspace features that are received for all subspaces inside an exemplary space (for example, the nine subspaces inside block 412) may form characteristics of the exemplary space.

In an exemplary embodiment, the plurality of subspace features may be received from a second user. In an exemplary embodiment, a “second user” may refer to a user that inputs data of exemplary plurality subspace features to a computer application in step 120. Therefore, an exemplary second user may be responsible for adding given residential house plan 400 to the database and thereby creating or expanding the database. An exemplary second user may be the same as or different from the first user.

FIG. 2B shows a window of a computer application for defining a user of the computer application, consistent with one or more exemplary embodiments of the present disclosure. An exemplary window 240 may be utilized to add the first user or the second user to an exemplary computer application so that the first user or the second user may be able to access and add data as described above.

Referring again to FIG. 1C, in an exemplary embodiment, step 122 may include mapping the characteristics to a second plurality of predefined numbers by mapping the plurality of subspace features to a respective predefined number of the second plurality of predefined numbers. Each exemplary subspace feature may be mapped to a predefined number in a similar procedure to step 104 described above for mapping each exemplary house feature to a predefined number.

FIG. 4D shows subspaces of residential units in a residential house plan mapped to predefined numbers, consistent with one or more exemplary embodiments of the present disclosure. An exemplary residential house plan 430 may be similar to given residential house plan 400 of FIG. 4A that is mapped to predefined numbers. Bold lines in FIG. 4D define borders of residential units of a same type (for example, an area 431 is a living room). In an exemplary embodiment, each subspace in residential house plan 430 may be mapped to a corresponding predefined number of the second plurality of predefined numbers according to features of the subspace. For example, subspace 432 that corresponds to sub-area 424 of FIG. 4C may be mapped to predefined number 111152 since sub-area 424 is a portion of a living room (mapped to 52 according to Table 2c) that is located in north west 302 (mapped to 111 according to Table 2c) and has a score of 1.

Referring again to FIGS. 1C and 4A, in an exemplary embodiment, step 124 may include storing the second plurality of predefined numbers and an image of given residential house plan 400 in the database. An exemplary image may be stored in a format selected by the second user, such as pdf, jpeg, etc. As a result, an exemplary database may be created or expanded by receiving characteristics of new residential house plans.

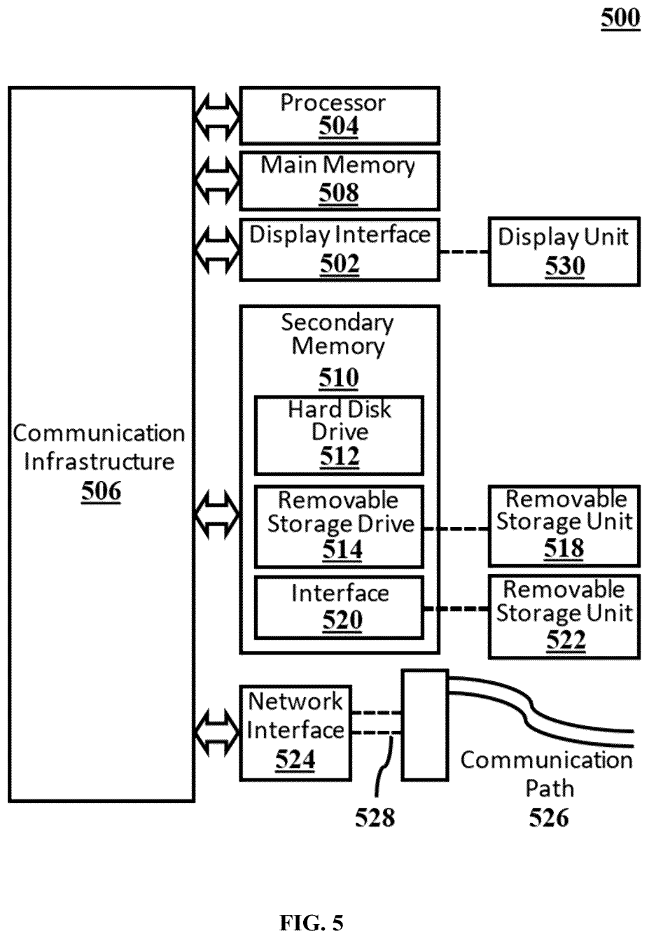

FIG. 5 shows an example computer system 500 in which an embodiment of the present invention, or portions thereof, may be implemented as computer-readable code, consistent with exemplary embodiments of the present disclosure. For example, different steps of method 100 may be implemented in computer system 500 using hardware, software, firmware, tangible computer readable media having instructions stored thereon, or a combination thereof and may be implemented in one or more computer systems or other processing systems. Hardware, software, or any combination of such may embody any of the modules and components in FIGS. 1A-4D.

If programmable logic is used, such logic may execute on a commercially available processing platform or a special purpose device. One ordinary skill in the art may appreciate that an embodiment of the disclosed subject matter can be practiced with various computer system configurations, including multi-core multiprocessor systems, minicomputers, mainframe computers, computers linked or clustered with distributed functions, as well as pervasive or miniature computers that may be embedded into virtually any device.

For instance, a computing device having at least one processor device and a memory may be used to implement the above-described embodiments. A processor device may be a single processor, a plurality of processors, or combinations thereof. Processor devices may have one or more processor “cores.”

An embodiment of the invention is described in terms of this example computer system 300. After reading this description, it will become apparent to a person skilled in the relevant art how to implement the invention using other computer systems and/or computer architectures. Although operations may be described as a sequential process, some of the operations may in fact be performed in parallel, concurrently, and/or in a distributed environment, and with program code stored locally or remotely for access by single or multiprocessor machines. In addition, in some embodiments the order of operations may be rearranged without departing from the spirit of the disclosed subject matter.

Processor device 504 may be a special purpose (e.g., a graphical processing unit) or a general-purpose processor device. As will be appreciated by persons skilled in the relevant art, processor device 504 may also be a single processor in a multi-core/multiprocessor system, such system operating alone, or in a cluster of computing devices operating in a cluster or server farm. Processor device 504 may be connected to a communication infrastructure 506, for example, a bus, message queue, network, or multi-core message-passing scheme.

In an exemplary embodiment, computer system 500 may include a display interface 502, for example a video connector, to transfer data to a display unit 530, for example, a monitor. Computer system 500 may also include a main memory 508, for example, random access memory (RAM), and may also include a secondary memory 510. Secondary memory 510 may include, for example, a hard disk drive 512, and a removable storage drive 514. Removable storage drive 514 may include a floppy disk drive, a magnetic tape drive, an optical disk drive, a flash memory, or the like. Removable storage drive 514 may read from and/or write to a removable storage unit 518 in a well-known manner. Removable storage unit 518 may include a floppy disk, a magnetic tape, an optical disk, etc., which may be read by and written to by removable storage drive 514. As will be appreciated by persons skilled in the relevant art, removable storage unit 518 may include a computer usable storage medium having stored therein computer software and/or data.

In alternative implementations, secondary memory 510 may include other similar means for allowing computer programs or other instructions to be loaded into computer system 500. Such means may include, for example, a removable storage unit 522 and an interface 520. Examples of such means may include a program cartridge and cartridge interface (such as that found in video game devices), a removable memory chip (such as an EPROM, or PROM) and associated socket, and other removable storage units 522 and interfaces 520 which allow software and data to be transferred from removable storage unit 522 to computer system 500.

Computer system 500 may also include a communications interface 524. Communications interface 524 allows software and data to be transferred between computer system 500 and external devices. Communications interface 524 may include a modem, a network interface (such as an Ethernet card), a communications port, a PCMCIA slot and card, or the like. Software and data transferred via communications interface 524 may be in the form of signals, which may be electronic, electromagnetic, optical, or other signals capable of being received by communications interface 524. These signals may be provided to communications interface 524 via a communications path 526. Communications path 526 carries signals and may be implemented using wire or cable, fiber optics, a phone line, a cellular phone link, an RF link or other communications channels.

In this document, the terms “computer program medium” and “computer usable medium” are used to generally refer to media such as removable storage unit 518, removable storage unit 522, and a hard disk installed in hard disk drive 512. Computer program medium and computer usable medium may also refer to memories, such as main memory 508 and secondary memory 510, which may be memory semiconductors (e.g. DRAMs, etc.).

Computer programs (also called computer control logic) are stored in main memory 508 and/or secondary memory 510. Computer programs may also be received via communications interface 524. Such computer programs, when executed, enable computer system 500 to implement different embodiments of the present disclosure as discussed herein. In particular, the computer programs, when executed, enable processor device 504 to implement the processes of the present disclosure, such as the operations in method 100 illustrated by flowcharts of FIG. 1A-FIG. 1C discussed above. Accordingly, such computer programs represent controllers of computer system 500. Where an exemplary embodiment of method 100 is implemented using software, the software may be stored in a computer program product and loaded into computer system 500 using removable storage drive 514, interface 520, and hard disk drive 512, or communications interface 524.

Embodiments of the present disclosure also may be directed to computer program products including software stored on any computer useable medium. Such software, when executed in one or more data processing device, causes a data processing device to operate as described herein. An embodiment of the present disclosure may employ any computer useable or readable medium. Examples of computer useable mediums include, but are not limited to, primary storage devices (e.g., any type of random access memory), secondary storage devices (e.g., hard drives, floppy disks, CD ROMS, ZIP disks, tapes, magnetic storage devices, and optical storage devices, MEMS, nanotechnological storage device, etc.).

The embodiments have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

While the foregoing has described what may be considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various implementations. This is for purposes of streamlining the disclosure, and is not to be interpreted as reflecting an intention that the claimed implementations require more features than are expressly recited in each claim. Rather, as the following claims reflect, inventive subject matter lies in less than all features of a single disclosed implementation. Thus, the following claims are hereby incorporated into the Detailed Description, with each claim standing on its own as a separately claimed subject matter.

While various implementations have been described, the description is intended to be exemplary, rather than limiting and it will be apparent to those of ordinary skill in the art that many more implementations and implementations are possible that are within the scope of the implementations. Although many possible combinations of features are shown in the accompanying figures and discussed in this detailed description, many other combinations of the disclosed features are possible. Any feature of any implementation may be used in combination with or substituted for any other feature or element in any other implementation unless specifically restricted. Therefore, it will be understood that any of the features shown and/or discussed in the present disclosure may be implemented together in any suitable combination. Accordingly, the implementations are not to be restricted except in light of the attached claims and their equivalents. Also, various modifications and changes may be made within the scope of the attached claims.

What is claimed is:

1. A method for search of residential house plans, the method comprising:
receiving, utilizing one or more processors, one or more house features from a first user;
mapping, utilizing the one or more processors, the one or more house features to one or more predefined numbers of a first plurality of predefined numbers stored in a database by mapping each of the one or more house features to a respective predefined number of the one or more predefined numbers;
finding, utilizing the one or more processors, a set of residential house plans stored in the database by mapping the one or more predefined numbers to each residential house plan in the set;
outputting, utilizing the one or more processors, one or more residential house plans in the set responsive to finding the set; and
adding, utilizing the one or more processors, a given residential house plan to the database by:
dividing the given residential house plan to a plurality of spaces;
dividing each of the plurality of spaces to a respective plurality of subspaces;
receiving characteristics of the given residential house plan by receiving a plurality of subspace features for each respective subspace of each respective plurality of subspaces from a second user;
mapping the characteristics to a second plurality of predefined numbers by mapping the plurality of subspace features to a respective predefined number of the second plurality of predefined numbers; and
storing the second plurality of predefined numbers and an image of the given residential house plan in the database,
wherein:
each of receiving the plurality of house features and receiving the plurality of subspace features comprises at least one of:
receiving a type of one or more residential units, the type comprising one of pillar, wall, window, door, lift, staircase, entrance, corridor, balcony, terrace, console, duct, storage room, filter, lobby, patio, void, pool, flower bed, kitchen, bathroom, toilet, laundry room, scullery, sewing room, dressing room, dining room, living room, TV room, study room, music room, billiard room, game room, recreation room, library, home cinema, master bedroom, kids room, guest room, closet, sick room, and worker room;
receiving a geographical situation of each of the one or more residential units, the geographical situation comprising one of north west, north, north east, west northwest, near to north, east northeast, west, center, east, west southwest, near to south, east southeast, south west, south, and south east;
receiving a score of each of the one or more residential units;
receiving building dimensions comprising a building width and a building length;
receiving a location of one or more land passages, the location comprising at least one of north, east, south, and west;
receiving a number of bedrooms; and
receiving a plan code comprising a four-digit number;
each of mapping each of the one or more house features to a respective predefined number of the one or more predefined numbers and mapping each of the plurality of subspace features to a respective predefined number of the second plurality of predefined numbers comprises:
mapping the geographical situation to first three digits of a six-digit number;
mapping the type of the one or more residential units to last two digits of the six-digit number; and
mapping the score to a fourth digit of the six-digit number; and
each of mapping each of the one or more house features to a respective predefined number of the one or more predefined numbers and mapping each of the plurality of subspace features to a respective predefined number of the second plurality of predefined numbers further comprises:
mapping each of the north, the east, the south, and the west to a respective digit of first four digits of a sixteen-digit number by:
setting the respective digit to a first value responsive to the each of the north, the east, the south, and the west being received; and
setting the respective digit to a second value responsive to the each of the north, the east, the south, and the west not being received;
mapping the building width to second four digits of the sixteen-digit number;
mapping the building length to third four digits of the sixteen-digit number; and
mapping the four-digit number to last four digits of the sixteen-digit number.

2. A method for search of residential house plans, the method comprising:
receiving, utilizing one or more processors, one or more house features from a first user;
mapping, utilizing the one or more processors, the one or more house features to one or more predefined numbers of a first plurality of predefined numbers stored in a database by mapping each of the one or more house features to a respective predefined number of the one or more predefined numbers; and
finding, utilizing the one or more processors, a set of residential house plans stored in the database by mapping the one or more predefined numbers to each residential house plan in the set.

3. The method of claim 2 further comprising:
adding, utilizing the one or more processors, a given residential house plan to the database by:
dividing the given residential house plan to a plurality of spaces;
dividing each of the plurality of spaces to a respective plurality of subspaces;
receiving characteristics of the given residential house plan by receiving a plurality of subspace features for each respective subspace of each respective plurality of subspaces from a second user;
mapping the characteristics to a second plurality of predefined numbers by mapping the plurality of subspace features to a respective predefined number of the second plurality of predefined numbers; and
storing the second plurality of predefined numbers and an image of the given residential house plan in the database.

4. The method of claim 3, wherein each of receiving the plurality of house features and receiving the plurality of subspace features comprises at least one of:
receiving a type of one or more residential units;
receiving a geographical situation of each of the one or more residential units;
receiving a score of each of the one or more residential units;
receiving building dimensions;
receiving a location of one or more land passages;
receiving a number of bedrooms; and
receiving a plan code.

5. The method of claim 4, wherein receiving the type of the one or more residential units comprises receiving one of pillar, wall, window, door, lift, staircase, entrance, corridor, balcony, terrace, console, duct, storage room, filter, lobby, patio, void, pool, flower bed, kitchen, bathroom, toilet, laundry room, scullery, sewing room, dressing room, dining room, living room, TV room, study room, music room, billiard room, game room, recreation room, library, home cinema, master bedroom, kids room, guest room, closet, sick room, and worker room.

6. The method of claim 4, wherein receiving the geographical situation comprises receiving one of north west, north, north east, west northwest, near to north, east northeast, west, center, east, west southwest, near to south, east southeast, south west, south, and south east.

7. The method of claim 4, wherein each of mapping each of the one or more house features to a respective predefined number of the one or more predefined numbers and mapping each of the plurality of subspace features to a respective predefined number of the second plurality of predefined numbers comprises:
mapping the geographical situation to first three digits of a six-digit number;
mapping the type of the one or more residential units to last two digits of the six-digit number; and
mapping the score to a fourth digit of the six-digit number.

8. The method of claim 7, wherein receiving the building dimensions comprises receiving a building width and a building length.

9. The method of claim 8, wherein receiving the location of the one or more land passages comprises receiving at least one of north, east, south, and west.

10. The method of claim 4, wherein receiving the plan code comprises receiving a four-digit number.

11. The method of claim 10, wherein each of mapping each of the one or more house features to a respective predefined number of the one or more predefined numbers and mapping each of the plurality of subspace features to a respective predefined number of the second plurality of predefined numbers further comprises:
mapping each of the north, the east, the south, and the west to a respective digit of first four digits of a sixteen-digit number by:
setting the respective digit to a first value responsive to the each of the north, the east, the south, and the west being received; and
setting the respective digit to a second value responsive to the each of the north, the east, the south, and the west not being received;
mapping the building width to second four digits of the sixteen-digit number;
mapping the building length to third four digits of the sixteen-digit number; and
mapping the four-digit number to last four digits of the sixteen-digit number.

12. The method of claim 2, further comprising:
outputting, utilizing the one or more processors, one or more residential house plans in the set responsive to finding the set.

13. A system for search of residential house plans, the system comprising:
a memory having processor-readable instructions stored therein; and
one or more processors configured to access the memory and execute the processor-readable instructions, which, when executed by the one or more processors configures the one or more processors to perform a method, the method comprising:
receiving one or more house features from a first user;
mapping the one or more house features to one or more predefined numbers of a first plurality of predefined numbers stored in a database by mapping each of the one or more house features to a respective predefined number of the one or more predefined numbers;
finding a set of residential house plans stored in the database by mapping the one or more predefined numbers to each residential house plan in the set; and
outputting one or more residential house plans in the set responsive to finding the set.

14. The system of claim 13, wherein the method further comprises:
adding a given residential house plan to the database by:
dividing the given residential house plan to a plurality of spaces;
dividing each of the plurality of spaces to a respective plurality of subspaces;
receiving characteristics of the given residential house plan by receiving a plurality of subspace features for each respective subspace of each respective plurality of subspaces from a second user;
mapping the characteristics to a second plurality of predefined numbers by mapping the plurality of subspace features to a respective predefined number of the second plurality of predefined numbers; and
storing the second plurality of predefined numbers and an image of the given residential house plan in the database.

15. The system of claim 14, wherein each of receiving the plurality of house features and receiving the plurality of subspace features comprises at least one of:
receiving a type of one or more residential units;
receiving a geographical situation of each of the one or more residential units;
receiving a score of each of the one or more residential units;
receiving building dimensions comprising a building width and a building length;
receiving a location of one or more land passages, the location comprising at least one of north, east, south, and west;
receiving a number of bedrooms; and
receiving a plan code.

16. The system of claim 15, wherein receiving the type of the one or more residential units comprises receiving one of pillar, wall, window, door, lift, staircase, entrance, corridor, balcony, terrace, console, duct, storage room, filter, lobby, patio, void, pool, flower bed, kitchen, bathroom, toilet, laundry room, scullery, sewing room, dressing room, dining room, living room, TV room, study room, music room, billiard room, game room, recreation room, library, home cinema, master bedroom, kids room, guest room, closet, sick room, and worker room.

17. The system of claim 15, wherein receiving the geographical situation comprises receiving one of north west, north, north east, west northwest, near to north, east northeast, west, center, east, west southwest, near to south, east southeast, south west, south, and south east.

18. The system of claim 15, wherein each of mapping each of the one or more house features to a respective predefined number of the one or more predefined numbers and mapping each of the plurality of subspace features to a respective predefined number of the second plurality of predefined numbers comprises:
mapping the geographical situation to first three digits of a six-digit number;
mapping the type of the one or more residential units to last two digits of the six-digit number; and
mapping the score to a fourth digit of the six-digit number.

19. The system of claim 15, wherein receiving the plan code comprises receiving a four-digit number.

20. The system of claim 19, wherein each of mapping each of the one or more house features to a respective predefined number of the one or more predefined numbers and mapping each of the plurality of subspace features to a respective predefined number of the second plurality of predefined numbers further comprises:
mapping each of the north, the east, the south, and the west to a respective digit of first four digits of a sixteen-digit number by:
setting the respective digit to a first value responsive to the each of the north, the east, the south, and the west being received; and
setting the respective digit to a second value responsive to the each of the north, the east, the south, and the west not being received;
mapping the building width to second four digits of the sixteen-digit number;
mapping the building length to third four digits of the sixteen-digit number; and
mapping the four-digit number to last four digits of the sixteen-digit number.
